(19) United States
(12) Patent Application Publication
(10) Pub. No.: US 2024/0427378 A1
(43) Pub. Date: Dec. 26, 2024

(54) FLEXIBLE DISPLAY APPARATUS AND METHOD OF MANUFACTURING THE SAME

(71) Applicant: Global Technologies Co., LTD, Hwaseong-si (KR)

(72) Inventors: Min Seon KIM, Hwaseong-si (KR); Yong Geun KIM, Suwon-si (KR)

(21) Appl. No.: 18/661,945

(22) Filed: May 13, 2024

(30) Foreign Application Priority Data
Jun. 20, 2023 (KR) 10-2023-0079073

(51) Int. Cl. G06F 1/16; H01L 27/15

(52) U.S. Cl. CPC G06F 1/1652; H01L 27/156

(57) ABSTRACT

Provided is a flexible display apparatus capable of displaying images when mounted on pillars or curved objects or rolled up, and a method of manufacturing the flexible display apparatus, the flexible display apparatus including a flexible printed circuit board (FPCB) made of a ductile material so as to be freely bent, a wiring layer provided on the FPCB, and a plurality of light-emitting device packages arranged in M rows and N columns on the wiring layer so as to be electrically connected to the wiring layer, wherein each light-emitting device package includes a package substrate, one or more light-emitting devices provided on the package substrate, and a driving device for applying a control signal to the light-emitting devices.

### CROSS-REFERENCE TO RELATED PATENT APPLICATION

This application claims the benefit of Korean Patent Application No. 10-2023-0079073, filed on Jun. 20, 2023, in the Korean Intellectual Property Office, the disclosure of which is incorporated herein in its entirety by reference.

### BACKGROUND OF THE INVENTION

### 1. Field of the Invention

The present invention relates to a flexible display apparatus and a method of manufacturing the same and, more particularly, to a flexible display apparatus capable of displaying images when mounted on pillars or curved objects or rolled up, and a method of manufacturing the flexible display apparatus.

### 2. Description of the Related Art

In general, flexible display apparatuses for displaying images by using a plurality of light-emitting diodes (LEDs) may include a flexible printed circuit board (FPCB) made of a flexible material to display the images when mounted on pillars or curved objects or rolled up.

The flexible display apparatuses necessarily require a driver integrated chip (IC) for controlling the plurality of LEDs, and existing flexible display apparatuses normally have a structure in which the plurality of LEDs are mounted on a top surface of the FPCB and the driver IC is mounted on a bottom surface of the FPCB.

However, according to the existing flexible display apparatuses, because components are mounted on the top and bottom surfaces of the FPCB, a total product thickness may increase, a manufacturing process may be complicated to cause difficulties in process and quality management, and the FPCB needs to be provided in a multilayer structure to greatly increase a product cost.

Furthermore, according to the existing flexible display apparatuses, because the driver IC integrally controls a large number of LEDs, the driver IC may increase in size, individual control of LEDs may not be facilitated to reduce image display performance, and heat may be severely and concentratively generated from the driver IC.

### SUMMARY OF THE INVENTION

The present invention provides a flexible display apparatus capable of achieving an ultra-thin product thickness by individually mounting a driver integrated chip (IC) in each light-emitting device package to control red (R), green (G), and blue (B) light-emitting diode (LED) chips, of facilitating process and quality management by simplifying a manufacturing process, of reducing a product cost by forming a flexible printed circuit board (FPCB) in a monolayer structure, of greatly increasing image display performance by facilitating individual control of LEDs, and of preventing concentration of heat by providing the driver IC in a minimum size for each light-emitting device package, and a method of manufacturing the flexible display apparatus. However, the above description is an example, and the scope of the present invention is not limited thereto.

According to an aspect of the present invention, there is provided a flexible display apparatus including a flexible printed circuit board (FPCB) made of a ductile material so as to be freely bent, a wiring layer provided on the FPCB, and a plurality of light-emitting device packages arranged in M rows and N columns on the wiring layer so as to be electrically connected to the wiring layer, wherein each light-emitting device package includes a package substrate, one or more light-emitting devices provided on the package substrate, and a driving device for applying a control signal to the light-emitting devices.

The light-emitting devices may include a red light-emitting diode (LED) chip, a green LED chip, and a blue LED chip such that one light-emitting device package forms one pixel.

The driving device may be a driver integrated chip (IC) including a surface provided with one or more terminals selected from among a power terminal, a driving voltage terminal, a control terminal, a feedback terminal, a brightness adjustment terminal, a light intensity correction terminal, a dummy terminal, and combinations thereof to apply control signals to the red, green, and blue LED chips.

In the light-emitting device package, the red, green, and blue LED chips may be disposed side by side on a portion of a top surface of the package substrate, and the driver IC is disposed on another portion of the top surface of the package substrate.

In the light-emitting device package, the red, green, and blue LED chips may be disposed side by side on a top surface of the package substrate, and the driver IC is provided inside the package substrate.

The light-emitting device package may further include a package protection member for protecting the light-emitting devices.

The package protection member may include at least one of a light-transmitting molding member made of a light-transmitting material including silicon or epoxy, a lens member, a photoconversion member including a phosphor material or quantum dots, a color filter member, an optical system, a reflective wall member, and combinations thereof.

The flexible display apparatus may further include a flexible protection member for protecting a bottom or top surface of the FPCB.

The flexible protection member may be a molding layer including at least one of urethane, silicon, rubber, synthetic resin, and combinations thereof.

According to another aspect of the present invention, there is provided a method of manufacturing a flexible display apparatus, the method including (a) preparing a flexible printed circuit board (FPCB) made of a ductile material so as to be freely bent, (b) forming a wiring layer on the FPCB, and (c) positioning and arranging a plurality of light-emitting device packages in M rows and N columns on the wiring layer so as to be electrically connected to the wiring layer, wherein, in step (c), each light-emitting device package is formed by forming one or more light-emitting devices, and a driving device for applying a control signal to the light-emitting devices, on a package substrate.

### BRIEF DESCRIPTION OF THE DRAWINGS

The above and other features and advantages of the present invention will become more apparent by describing in detail embodiments thereof with reference to the attached drawings in which:

FIG. 1 is an overall perspective view of a flexible display apparatus according to some embodiments of the present invention;

FIG. 2 is an enlarged perspective view of the flexible display apparatus of FIG. 1;

FIG. 3 is a cross-sectional view cut along line III-III of the flexible display apparatus of FIG. 1;

FIG. 4 is an enlarged perspective view of an example of a light-emitting device package applied to the flexible display apparatus of FIG. 1;

FIG. 5 is an enlarged perspective view of another example of a light-emitting device package applied to the flexible display apparatus of FIG. 1;

FIGS. 6 to 9 are sequential cross-sectional views for describing a procedure of manufacturing a flexible display apparatus, according to some embodiments of the present invention; and

FIG. 10 is a flowchart of a method of manufacturing a flexible display apparatus, according to some embodiments of the present invention.

### DETAILED DESCRIPTION OF THE INVENTION

Hereinafter, the present invention will be described in detail by explaining embodiments of the invention with reference to the attached drawings.

The invention may, however, be embodied in many different forms and should not be construed as being limited to the embodiments set forth herein; rather, these embodiments are provided so that this disclosure will be thorough and complete, and will fully convey the concept of the invention to one of ordinary skill in the art. In the drawings, the thicknesses or sizes of layers are exaggerated for clarity and convenience of explanation.

It will be understood that when an element, such as a layer, a region, or a substrate, is referred to as being “on”, “connected to”, “stacked on”, or “coupled to” another element, it may be directly on, connected to, stacked on, or coupled to the other element or intervening elements may be present. In contrast, when an element is referred to as being “directly on”, “directly connected to”, “directly stacked on”, or “directly coupled to” another element or layer, there are no intervening elements or layers present. Like reference numerals denote like elements throughout. As used herein, the term “and/or” includes any and all combinations of one or more of the associated listed items.

It will be understood that, although the terms first, second, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

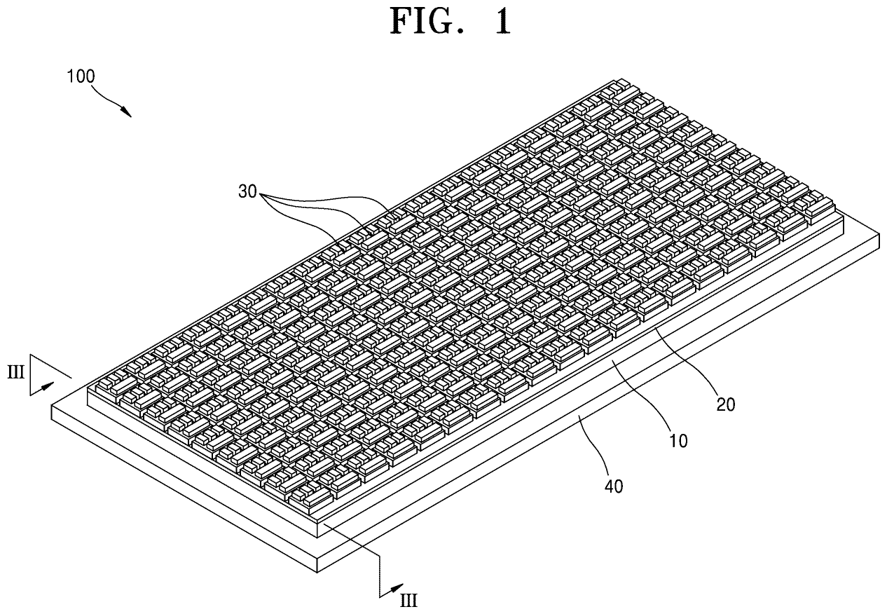

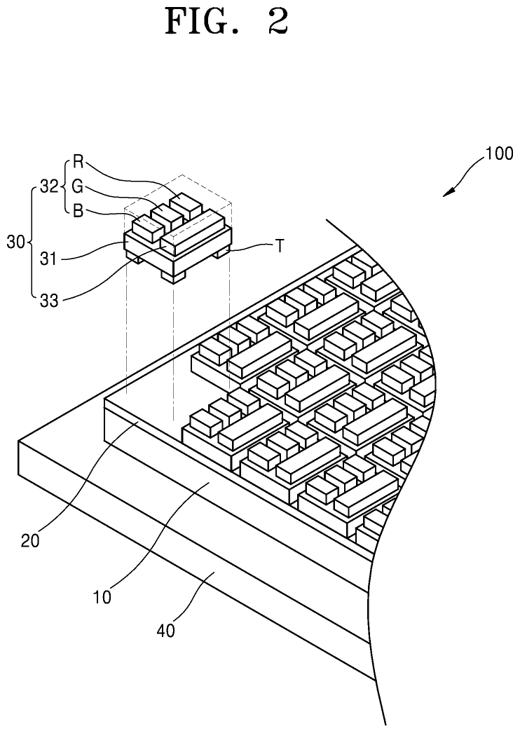

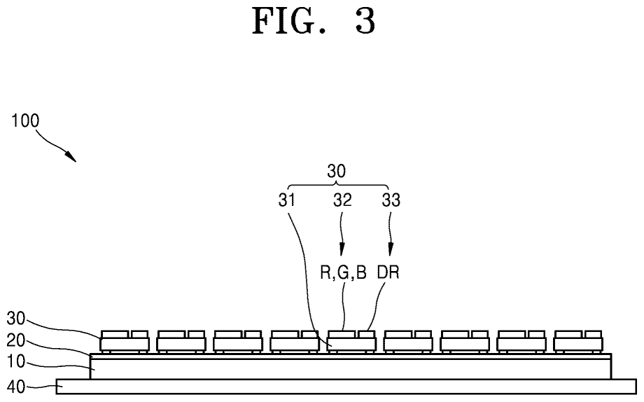

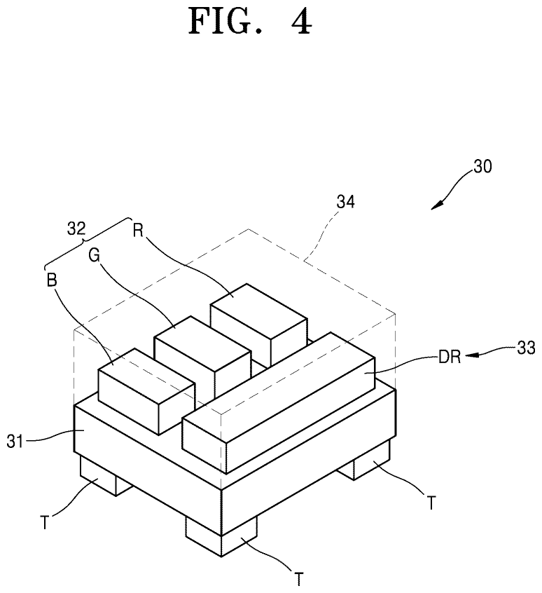

FIG. 1 is an overall perspective view of a flexible display apparatus 100 according to some embodiments of the present invention, FIG. 2 is an enlarged perspective view of the flexible display apparatus 100 of FIG. 1, FIG. 3 is a cross-sectional view cut along line III-III of the flexible display apparatus 100 of FIG. 1, and FIG. 4 is an enlarged perspective view of an example of a light-emitting device package 30 applied to the flexible display apparatus 100 of FIG. 1.

Initially, as shown in FIGS. 1 to 4, the flexible display apparatus 100 according to some embodiments of the present invention may include a flexible printed circuit board (FPCB) 10, a wiring layer 20, light-emitting device packages 30, and a flexible protection member 40.

The FPCB 10 is a circuit board made of a flexible ductile insulating material so as to be freely bent, and may be made of a ductile material, e.g., polyimide, polypropene, propylene ethylene, polyethylene, rubber, urethane, polyolefin, polyester, polypropylene, or polyethylene terephthalate.

The wiring layer 20 is a conductive layer made of a type of conductive metal material and patterned on the FPCB 10 through plating, transcription, coating, sputtering, etching, development, printing, or the like, and may be made of any conductive material or metal material such as aluminum, copper, nickel, silver, gold, platinum, or iron.

A plurality of light-emitting device packages 30 may be arranged in M rows and N columns on the wiring layer 20 so as to be electrically connected to the wiring layer 20.

Each light-emitting device package 30 may include a package substrate 31, one or more light-emitting devices 32 provided on the package substrate 31, a driving device 33 for applying a control signal to the light-emitting devices 32, and a package protection member 34.

The light-emitting devices 32 may include a red light-emitting diode (LED) chip R, a green LED chip G, and a blue LED chip B such that one light-emitting device package 30 forms one pixel.

In the light-emitting device package 30, as shown in FIG. 4, the red, green, and blue LED chips R, G, and B may be disposed side by side on a portion of a top surface of the package substrate 31, and a driver integrated chip (IC) DR may be disposed on another portion of the top surface of the package substrate 31.

The light-emitting devices 32 may be provided as flip-chip LEDs each including first and second pads on a bottom surface thereof.

The light-emitting devices 32 may be provided as any of red, green, and blue flip-chip LEDs, but are not limited thereto and may also be provided as various colored inorganic non-flip-chip LEDs each including pads exposed on a top surface thereof. The light-emitting devices 32 may be provided not only as general LEDs but also as any other type of LEDs such as mini-LEDs or micro-LEDs.

That is, although not shown in the drawings, the light-emitting devices 32 may be provided as light-emitting devices in which wire bonding is applied to terminals or partially applied only to a first or second terminal, or lateral or vertical light-emitting devices, but flip-chip light-emitting devices may be used to produce compact and ultra-thin products.

The light-emitting devices 32 may be formed by epitaxially growing a nitride semiconductor such as InN, AlN, InGaN, AlGaN, or InGaAlN on a growth substrate such as a sapphire substrate or a silicon carbide substrate based on a vapor deposition method such as metal organic chemical vapor deposition (MOCVD). In addition to the nitride semiconductor, the light-emitting devices 32 may also be formed using a semiconductor such as ZnO, ZnS, ZnSe, SiC, GaP, GaAlAs, or AlInGaP. These semiconductors may use a structure in which an n-type semiconductor layer, an emissive layer, and a p-type semiconductor layer are stacked on one another in the listed order. The emissive layer (or active layer) may use a stacked semiconductor of a multi-quantum well structure or a single quantum well structure, or a stacked semiconductor of a double heterostructure. The light-emitting devices 32 may be selected to have an arbitrary wavelength depending on the purpose thereof, e.g., display or lighting.

Herein, the growth substrate may use an insulating, conductive, or semiconductor substrate depending on the necessity thereof. For example, the growth substrate may be a sapphire, SiC, Si, MgAl₂O₄, MgO, LiAlO₂, LiGaO₂, or GaN substrate. To epitaxially grow GaN, the growth substrate may be provided as a GaN substrate including a homogeneous material.

The driving device 33 may be a driver IC DR including a surface provided with one or more terminals T selected from among a power terminal, a driving voltage terminal, a control terminal, a feedback terminal, a brightness adjustment terminal, a light intensity correction terminal, a dummy terminal, and combinations thereof to apply control signals to the red, green, and blue LED chips R, G, and B.

The driving device 33 includes one or more driving circuits to serve as a type of driver IC, and the driving circuits may include various types of circuits for supplying power, controlling a driving voltage, processing a feedback signal, adjusting the brightness of the light-emitting devices 32, and correcting the intensity of light of the light-emitting devices 32 based on a reference light intensity of other light-emitting devices.

The driving device 33 may include a semiconductor substrate formed on a semiconductor wafer such as a silicon wafer by using an IC process, and the semiconductor substrate may include multiple layers of semiconductor materials and the driving circuits on different layers may be electrically connected using a metal redistribution layer (RDL).

To input or output signals to or from the driving circuits, the driving device 33 may include one or more terminals T provided on a surface of the semiconductor substrate to receive a power signal or input/output signals.

The terminals T may be made of an electrically conductive material having high electrical conductivity, e.g., copper (Cu), nickel (Ni), silver (Ag), or gold (Au), and provided as various types of solders, bumps, or pads.

Specifically, for example, the terminals T may include one or more selected from among a power terminal, a driving voltage terminal, a control terminal, a feedback terminal, a brightness adjustment terminal, a light intensity correction terminal, a dummy terminal, and combinations thereof.

The package protection member 34 is a type of sealing or molding member for protecting the light-emitting devices 32 or the driving device 33, and the package protection member 34 may include at least one of a light-transmitting molding member made of a light-transmitting material including silicon or epoxy, a lens member, a photoconversion member including a phosphor material or quantum dots, a color filter member, an optical system, a reflective wall member, and combinations thereof.

The package protection member 34 may be provided as a light-transmitting molding member formed by casting a light-transmitting material including silicon or epoxy.

However, the package protection member 34 is not limited to the light-transmitting molding member and may also be provided as a photoconversion member including a phosphor material or quantum dots, a color filter member, an optical system, or a reflective wall member.

Herein, the phosphor material needs to basically comply with stoichiometry, and each element may be replaced by another element of the same group in the periodic table. For example, strontium (Sr) may be replaced by barium (Ba), calcium (Ca), or magnesium (Mg) of the alkaline-earth group (group II), yttrium (Y) may be replaced by terbium (Tb), lutetium (Lu), scandium (Sc), or gadolinium (Gd) of the lanthanide series. In addition, europium (Eu), which is an activator, may be replaced by cerium (Ce), terbium (Tb), praseodymium (Pr), erbium (Er), or ytterbium (Yb) depending on a desired energy level, and the activator may be used solely or a coactivator may be added for property modification.

The quantum dots may be nanometer-sized particles which may have optical properties based on quantum confinement and include at least one of, for example, group IV elements, group II-VI compounds, group II-V compounds, group III-VI compounds, group III-V compounds, group IV-VI compounds, group I-III-VI compounds, group II-IV-VI compounds, and group II-IV-V compounds.

The quantum dots may include at least one of ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InP, InSb, AlAs, AlN, AlP, AlSb, TlN, TlP, TlAs, TlSb, PbO, PbS, PbSe, PbTe, and germanium (Ge) or silicon (Si).

The quantum dots may have a structure including a CdSe or InP core (3 nm to 10 nm), a ZnS or ZnSe shell (0.5 nm to 2 nm), and a ligand for stabilizing the core and the shell, and have optical properties capable of displaying various colors depending on sizes.

The quantum dots may be included in a physical structure or another form, and include a monomer which may be polymerized into a desired physical structure such as a film.

Specifically, for example, in addition to the form of a sheet, the quantum dots may be injected in the form of paste together with various binders and then hardened, or provided in various forms of fluid, e.g., liquid or gel.

The photoconversion member may include two or more types of phosphor and quantum dot materials with different emission wavelengths and be used by mixing the phosphor and the quantum dots.

The flexible protection member 40 is a type of coating or sealing member for protecting a bottom or top surface of the FPCB 10, and may be a molding layer including at least one of urethane, silicon, rubber, synthetic resin, and combinations thereof.

Therefore, according to the present invention, when power or a control signal is input to the driving device 33 of the light-emitting device packages 30 through the wiring layer 20, the driving device 33 may supply power in units of RGB pixels by applying control signals to the red, green, and blue LED chips R, G, and B, apply and control a driving voltage, adjust the brightness by using a feedback function, or correct the intensity of light to finely and precisely express colors and contrast in units of individual pixels.

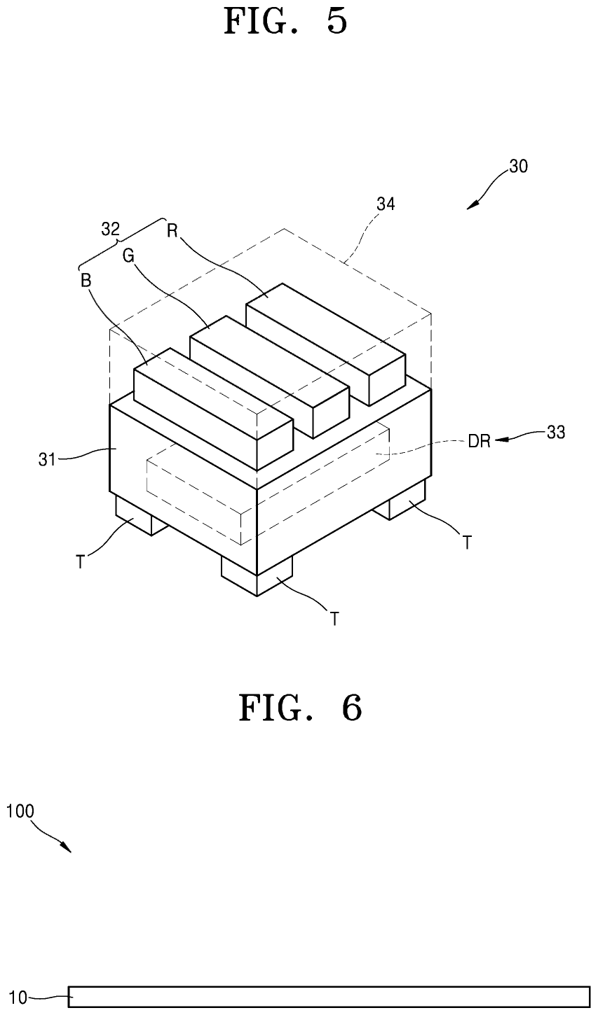

FIG. 5 is an enlarged perspective view of another example of the light-emitting device package 30 applied to the flexible display apparatus 100 of FIG. 1.

As shown in FIG. 5, as another example of the light-emitting device package 30 applied to the flexible display apparatus 100 of FIG. 1, in the light-emitting device package 30, the red, green, and blue LED chips R, G, and B may be disposed side by side on the top surface of the package substrate 31, and the driver IC DR may be provided inside the package substrate 31.

Electrical connection between the red, green, and blue LED chips R, G, and B and the driver IC DR or between the driver IC DR and the terminals T may be made by forming through electrodes (not shown).

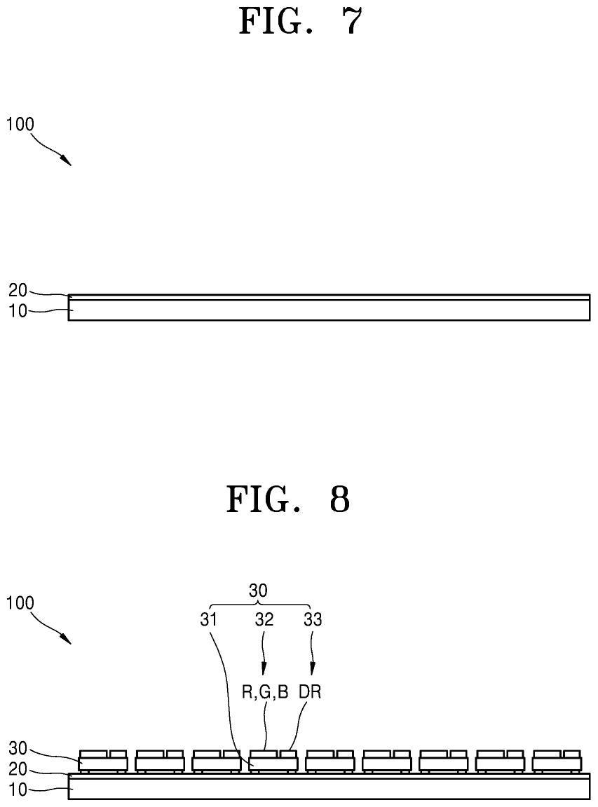

FIGS. 6 to 9 are sequential cross-sectional views for describing a procedure of manufacturing the flexible display apparatus 100, according to some embodiments of the present invention.

The procedure of manufacturing the flexible display apparatus 100, according to some embodiments of the present invention, will now be described with reference to FIGS. 6 to 9. Initially, as shown in FIG. 6, the FPCB 10 made of a ductile material so as to be freely bent may be prepared.

Then, as shown in FIG. 7, the wiring layer 20 may be formed on the FPCB 10 by using a printed circuit process. In this case, the wiring layer 20 may include not only power application wires for applying power but also signal transmission wires for applying various control signals.

Then, as shown in FIG. 8, a plurality of light-emitting device packages 30 may be positioned and arranged in M rows and N columns on the wiring layer 20 so as to be electrically connected to the wiring layer 20. In this case, each light-emitting device package 30 may be formed by forming one or more light-emitting devices 32, and the driving device 33 for applying a control signal to the light-emitting devices 32, on the package substrate 31.

Then, as shown in FIG. 9, when necessary, the flexible protection member 40 may be formed on a bottom (or top) surface of the FPCB 10 to protect the bottom or top surface of the FPCB 10.

Therefore, according to the present invention, an ultra-thin product thickness may be achieved by individually mounting the driver IC DR in each light-emitting device package 30 to control R, G, and B LED chips, process and quality management may be facilitated by simplifying a manufacturing process, a product cost may be reduced by forming the FPCB 10 in a monolayer structure, image display performance may be greatly increased by facilitating individual control of LEDs, and concentration of heat may be prevented by providing the driver IC DR in a minimum size for each light-emitting device package 30.

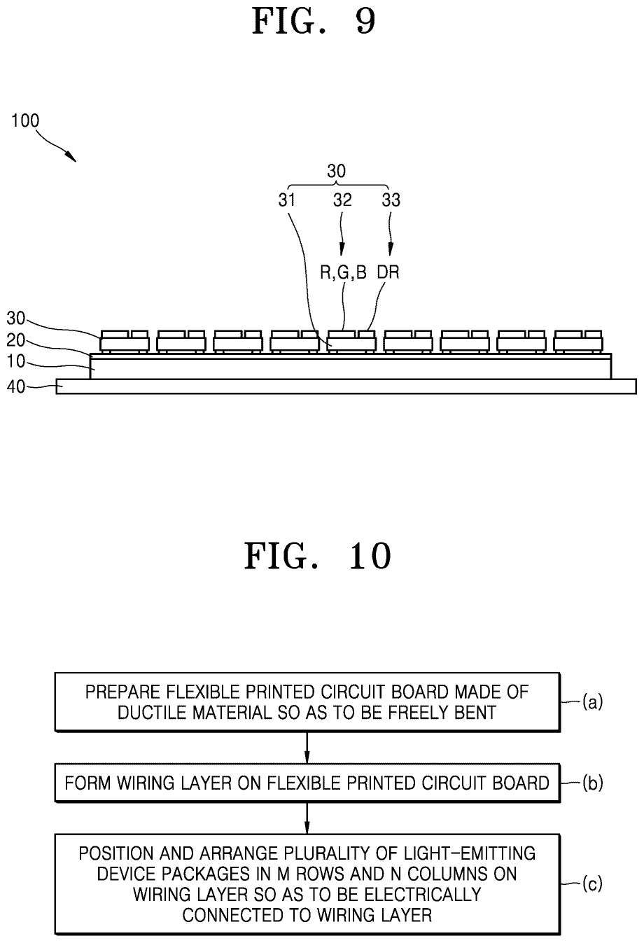

FIG. 10 is a flowchart of a method of manufacturing the flexible display apparatus 100, according to some embodiments of the present invention.

As shown in FIGS. 1 to 10, the method of manufacturing the flexible display apparatus 100, according to some embodiments of the present invention, may include (a) preparing the FPCB 10 made of a ductile material so as to be freely bent, (b) forming the wiring layer 20 on the FPCB 10, and (c) positioning and arranging a plurality of light-emitting device packages 30 in M rows and N columns on the wiring layer 20 so as to be electrically connected to the wiring layer 20.

In step (c), each light-emitting device package 30 may be formed by forming one or more light-emitting devices 32, and the driving device 33 for applying a control signal to the light-emitting devices 32, on the package substrate 31.

According to the afore-described embodiments of the present invention, an ultra-thin product thickness may be achieved by individually mounting a driver IC in each light-emitting device package to control R, G, and B LED chips, process and quality management may be facilitated by simplifying a manufacturing process, a product cost may be reduced by forming an FPCB in a monolayer structure, image display performance may be greatly increased by facilitating individual control of LEDs, and concentration of heat may be prevented by providing the driver IC in a minimum size for each light-emitting device package. However, the scope of the present invention is not limited to the above effects.

While the present invention has been particularly shown and described with reference to embodiments thereof, it will be understood by one of ordinary skill in the art that various changes in form and details may be made therein without departing from the scope of the present invention as defined by the following claims.

What is claimed is:

1. A flexible display apparatus comprising:
a flexible printed circuit board (FPCB) made of a ductile material so as to be freely bent;
a wiring layer provided on the FPCB; and
a plurality of light-emitting device packages arranged in M rows and N columns on the wiring layer so as to be electrically connected to the wiring layer,
wherein each light-emitting device package comprises:
a package substrate;
one or more light-emitting devices provided on the package substrate; and
a driving device for applying a control signal to the light-emitting devices.

2. The flexible display apparatus of claim 1, wherein the light-emitting devices comprise a red light-emitting diode (LED) chip, a green LED chip, and a blue LED chip such that one light-emitting device package forms one pixel.

3. The flexible display apparatus of claim 2, wherein the driving device is a driver integrated chip (IC) comprising a surface provided with one or more terminals selected from among a power terminal, a driving voltage terminal, a control terminal, a feedback terminal, a brightness adjustment terminal, a light intensity correction terminal, a dummy terminal, and combinations thereof to apply control signals to the red, green, and blue LED chips.

4. The flexible display apparatus of claim 3, wherein, in the light-emitting device package, the red, green, and blue LED chips are disposed side by side on a portion of a top surface of the package substrate, and the driver IC is disposed on another portion of the top surface of the package substrate.

5. The flexible display apparatus of claim 3, wherein, in the light-emitting device package, the red, green, and blue LED chips are disposed side by side on a top surface of the package substrate, and the driver IC is provided inside the package substrate.

6. The flexible display apparatus of claim 1, wherein the light-emitting device package further comprises a package protection member for protecting the light-emitting devices.

7. The flexible display apparatus of claim 6, wherein the package protection member comprises at least one of a light-transmitting molding member made of a light-transmitting material comprising silicon or epoxy, a lens member, a photoconversion member comprising a phosphor material or quantum dots, a color filter member, an optical system, a reflective wall member, and combinations thereof.

8. The flexible display apparatus of claim 1, further comprising a flexible protection member for protecting a bottom or top surface of the FPCB.

9. The flexible display apparatus of claim 8, wherein the flexible protection member is a molding layer comprising at least one of urethane, silicon, rubber, synthetic resin, and combinations thereof.

10. A method of manufacturing a flexible display apparatus, the method comprising:
(a) preparing a flexible printed circuit board (FPCB) made of a ductile material so as to be freely bent;
(b) forming a wiring layer on the FPCB; and
(c) positioning and arranging a plurality of light-emitting device packages in M rows and N columns on the wiring layer so as to be electrically connected to the wiring layer,
wherein, in step (c), each light-emitting device package is formed by forming one or more light-emitting devices, and a driving device for applying a control signal to the light-emitting devices, on a package substrate.
